(19) United States
(12) Patent Application Publication
(10) Pub. No.: US 2024/0232488 A9
(43) Pub. Date: Jul. 11, 2024

(54) FAST FPGA REVERSE ENGINEERING FOR HARDWARE METERING AND FINGERPRINTING

(71) Applicant: University Of Cincinnati, Cincinnati, OH (US)

(72) Inventors: John Martin Emmert, Dayton, OH (US); Anvesh Perumalla, Dayton, OH (US); Heiko Stowasser, Cincinnati, OH (US)

(73) Assignee: University Of Cincinnati, Cincinnati, OH (US)

(21) Appl. No.: 18/494,300

(22) Filed: Oct. 25, 2023

Related U.S. Application Data
(60) Provisional application No. 63/419,098, filed on Oct. 25, 2022.
(60) Provisional application No. 63/510,723, filed on Jun. 28, 2023.

(51) Int. Cl. G06F 30/331

(52) U.S. Cl. CPC G06F 30/331

(57) ABSTRACT

An apparatus may include a processor configured to synthesize a first configuration file associated with a target field-programmable gate array (FPGA), and a second configuration file associated with the target FPGA, wherein first look-up-table (LUT) bits of the first configuration file are the logical inverse of second LUT bits of the second configuration file, and first non-LUT bits of the first configuration file are the same as second non-LUT bits of the second configuration file, and generate a LUT mask indicating which bits of the first configuration file and the second configuration file correspond to the first LUT bits and the second LUT bits by performing a bit-wise exclusive OR operation between the first configuration file and the second configuration file.

### CROSS-REFERENCE TO RELATED APPLICATION

This application claims priority to U.S. Provisional Application No. 63/419,098 filed on Oct. 25, 2022 and U.S. Provisional Application No. 63/510,723 filed on Jun. 28, 2023, each of which is incorporated herein by reference in its entirety.

### FEDERALLY SPONSORED RESEARCH STATEMENT

This invention was made with Government support under Contract No. 1916722 awarded by the National Science Foundation. The Government has certain rights in the invention.

### TECHNICAL FIELD

The present specification relates to protection of integrated circuits, and more particularly, to fast FPGA reverse engineering for hardware metering and fingerprinting.

### BACKGROUND

Field programmable gate arrays (FPGAs) are an integral part of many computing and data processing systems. FPGAs may be used for prototyping and for fielding integrated circuit (IC) systems. In order to lower design cost and decrease time to market, FPGA designers often rely on third party intellectual property that can be precompiled. In particular, third party firmware may be used to program an FPGA to operate in a particular manner.

However, by receiving third party firmware in binary form, it may be difficult for a user to detect any malicious functionality that may be hidden inside. For example, potentially hidden Trojan circuitry may leak sensitive information, allow control of the system to be forfeited, or disable the system. Accordingly, it is desirable to be able to quickly and easily reverse engineer firmware to ensure that the firmware does what it is supposed to do, and does not include any additional malicious or unexpected functionality.

### SUMMARY

In an embodiment, an apparatus may include a processor configured to synthesize a first configuration file associated with a target field-programmable gate array (FPGA), and a second configuration file associated with the target FPGA, wherein first look-up-table (LUT) bits of the first configuration file are the logical inverse of second LUT bits of the second configuration file, and first non-LUT bits of the first configuration file are the same as second non-LUT bits of the second configuration file; and generate a LUT mask indicating which bits of the first configuration file and the second configuration file correspond to the first LUT bits and the second LUT bits by performing a bit-wise exclusive OR operation between the first configuration file and the second configuration file.

In another embodiment, a method may include synthesizing a first configuration file associated with a target field-programmable gate array (FPGA), and a second configuration file associated with the target FPGA, wherein first look-up-table (LUT) bits of the first configuration file are the logical inverse of second LUT bits of the second configuration file, and first non-LUT bits of the first configuration file are the same as second non-LUT bits of the second configuration file; and generating a LUT mask indicating which bits of the first configuration file and the second configuration file correspond to the first LUT bits and the second LUT bits by performing a bit-wise exclusive OR operation between the first configuration file and the second configuration file.

### BRIEF DESCRIPTION OF THE DRAWINGS

The embodiments set forth in the drawings are illustrative and exemplary in nature and not intended to limit the disclosure. The following detailed description of the illustrative embodiments can be understood when read in conjunction with the following drawings, where like structure is indicated with like reference numerals and in which:

FIG. 1 schematically depicts an example island style FPGA architecture, according to one or more embodiments shown and described herein;

FIG. 2 shows a portion of an example FPGA configuration file, according to one or more embodiments shown and described herein;

FIG. 3 shows a schematic diagram of an example computing device, according to one or more embodiments shown and described herein;

FIG. 4 depicts a schematic diagram of the memory modules of the computing device of FIG. 3, according to one or more embodiments shown and described herein;

FIG. 5A depicts a schematic diagram of an example input signal connection, according to one or more embodiments shown and described herein;

FIG. 5B depicts a schematic diagram of another example input signal connection, according to one or more embodiments shown and described herein;

FIG. 6 shows example pseudocode for generating the example input signal connections of FIGS. 5A and 5B, according to one or more embodiments shown and described herein;

FIG. 7 depicts a schematic diagram of an example input signal connection, according to one or more embodiments shown and described herein;

FIG. 8 shows example pseudocode for generating the example input signal connection of FIG. 7, according to one or more embodiments shown and described herein;

FIG. 9 shows example pseudocode for programming memory cells of an FPGA, according to one or more embodiments shown and described herein;

FIG. 10 shows example test results, according to one or more embodiments shown and described herein; and

FIG. 11 depicts a flowchart of an example method for operating the computing device of FIG. 3, according to one or more embodiments shown and described herein.

### DETAILED DESCRIPTION

The embodiments disclosed herein are directed to FPGA reverse engineering for hardware metering and fingerprinting. An FPGA may be programmed with firmware comprising a bit file. In embodiments, this file may be referred to as firmware, a bit file, or a configuration file. If a bit file is provided by a third party, it can be difficult to ensure that the bit file will program the FPGA to operate as desired. Even if the programmed FPGA performs its specified functions, it may also perform additional unexpected or malicious functions. Accordingly, it is desirable to be able to reverse engineer an FPGA programming bit file prior to loading it onto an FPGA in order to ensure that it will not perform any unexpected or malicious functions.

Standard reverse engineering of FPGA programming bit files requires knowledge of how the bits in the bitstream map to the configurable logic for specified FPGAs. There are several known methods to obtain this mapping, such as Project X-Ray, which targets 7 Series Xilinx FPGAs. However, the known methods of reverse engineering FPGA bit files are limited either to a specific FPGA or to a specific manufacturer's toolchain. In embodiments disclosed herein, a method is provided for quickly and easily reverse engineering FPGA programming bit files to locate FPGA LUT functionality that is not tied to a specific FPGA or toolchain.

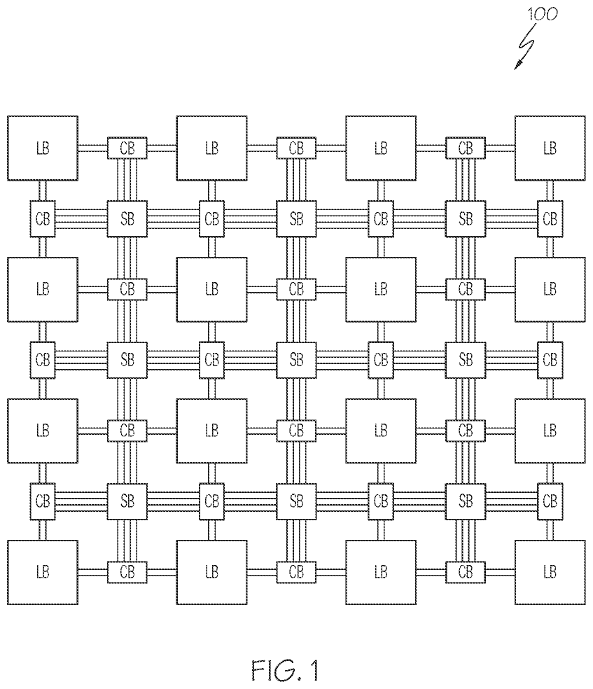

Turning now to the figures, FIG. 1 schematically depicts an architecture of an example FPGA 100. The example FPGA 100 comprises a plurality of logic blocks (LB), and a plurality of switches (SB) and connector boxes (CB) that make up routing channels to interconnect the logic blocks. For purposes of illustration, the FPGA 100 comprises an island-style architecture, in which each individual logic block acts as an island, and is connected to the other blocks via routing channels comprising the connector boxes and switches. The methods disclosed herein are applicable to FPGAs with island-style architecture, which is typical of most commercially available FPGAs. For FPGAs that have other programmable logic structures, such as built-in multipliers, clock-managers, phase-locked loops, RAM components, ARM processors, and the like, the disclosed methods may be applied to the logic blocks of such FPGAs.

In the example of FIG. 1, each logic block of the FPGA 100 may comprise one or more programmable look-up-tables (LUTs) to implement the functionality of the logic block. Each LUT may comprise a plurality of memory cells, with each memory cell storing one bit. Each LUT may implement a digital function of its input, which may be defined by the value of the memory cells of the LUT. For a 3-input LUT, 8 memory cells (2³) are needed to implement the LUT functionality. For a 4-input LUT, 16 memory cells (2⁴) are needed to implement the LUT functionality, and so on. An FPGA may have thousands of LUTs to implement the functionality of the FPGA.

To program an FPGA, a firmware or bit file is loaded onto the FPGA. In particular, the bit file loads 1's or 0's into each memory cell of each LUT of the FPGA. The specific configuration of 1's and 0's loaded into the memory cells of the LUTs defines the operation of the FPGA. Accordingly, embodiments disclosed herein allow for the bit file to be analyzed to determine how it will program each of the memory cells of the LUTs on an FPGA when the FPGA is programmed using the bit file. This may allow for analysis of the functionality of the FPGA after being programmed with the bit file to ensure that no unexpected or malicious operation will occur.

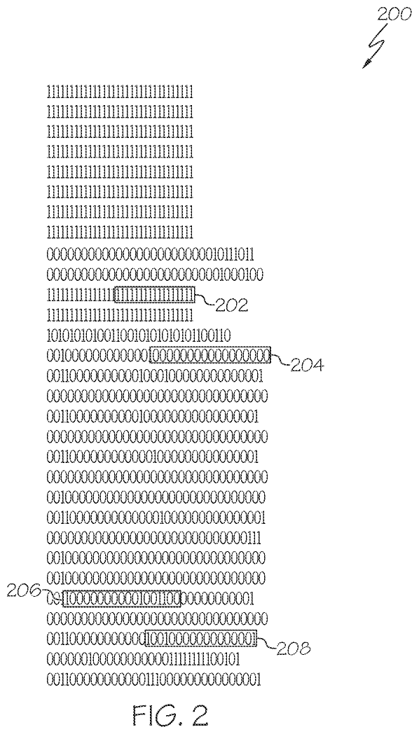

In embodiments disclosed herein, the bits of a bit file used to program an FPGA are mapped to FPGA hardware. FIG. 2 shows a portion of an example bit file 200 that may be used to program an FPGA. In the example of FIG. 2, the bit file 200 includes 32,354,512 bits, of which a small portion is shown. When the bit file 200 is used to program a particular FPGA, certain bits of the bit file 200 will be loaded into memory cells of LUTs. Other bits of the bit file 200 are used for other purposes and other components of the FPGA, such as programming switches, address bits, header information, and the like. As used herein, LUT bits refer bits of a bit file that are loaded into LUT memory cells as non-LUT bits ref to bits of a bit file that are used for other purposes and are not loaded into LUT memory cells.

In the example of FIG. 2, when the bit file 200 is used to program a particular FPGA, the bitstreams 202, 204, 206, and 208 are used as LUT bits, while the other bits shown in the example of FIG. 2 are used as non-LUT bits. Accordingly, in embodiments, a method is disclosed for identifying LUT bits in a bit file. That is, a method is disclosed for mapping particular bits of an FPGA bit file to memory cells of the LUTs in the FPGA to be programmed by the bit file.

In embodiments, a bitstream LUT mask is created for a particular FPGA that identifies LUT bits for an FPGA. For example, a LUT mask may indicate that bits in the positions of bitstreams 202, 204, 206, and 208 are LUT bits. Accordingly, after a LUT mask is created for an FPGA, when a third party configuration file is to be used to program the FPGA, the LUT mask may be applied to the third party configuration file to identify which bits of the configuration file are LUT bits. This may be used to determine the functionality of the FPGA programmed with the configuration file to ensure that no malicious or unexpected functionality will be implemented. These techniques are discussed in further detail below.

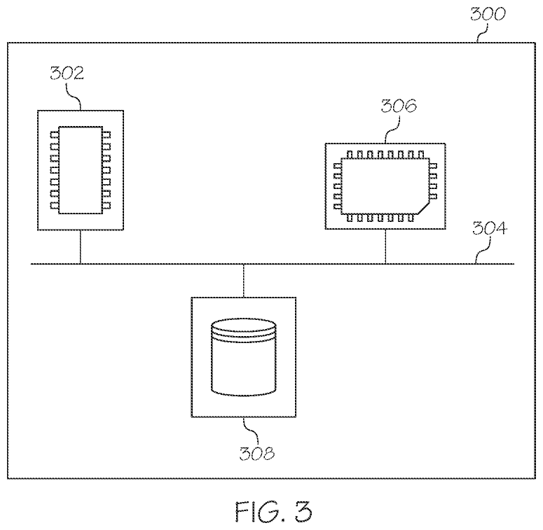

Turning now to FIG. 3, a schematic diagram of the hardware components of an example computing device 300 are shown. The computing device 300 may perform the functions of fast FPGA reverse engineering for hardware metering and fingerprinting, as disclosed herein. The computing device 300 may be any type of computing device able to perform the functions disclosed herein (e.g., a desktop computer, a laptop computer, a cloud computing device, a tablet, a smartphone, or a dedicated hardware device).

As shown in FIG. 3, the computing device 300 includes a processor 302, a communication path 304, one or more memory modules 306, and a data storage component 308, the details of which will be set forth in the following paragraphs.

The processor 302 may be any device capable of executing machine readable and executable instructions. Accordingly, the processor 302 may be a controller, an integrated circuit, a microchip, a computer, or any other computing device. The processor 302 is coupled to a communication path 304 that provides signal interconnectivity between various modules of the computing device 300. Accordingly, the communication path 304 may allow the modules coupled to the communication path 304 to operate in a distributed computing environment. Specifically, each of the modules may operate as a node that may send and/or receive data. As used herein, the term “communicatively coupled” means that coupled components are capable of exchanging data signals with one another such as, for example, electrical signals via conductive medium, electromagnetic signals via air, optical signals via optical waveguides, and the like.

Accordingly, the communication path 304 may be formed from any medium that is capable of transmitting a signal such as, for example, conductive wires, conductive traces, optical waveguides, or the like. In some embodiments, the communication path 304 may facilitate the transmission of wireless signals, such as Wi-Fi, Bluetooth®, Near Field Communication (NFC) and the like. Moreover, the communication path 304 may be formed from a combination of mediums capable of transmitting signals. In one embodiment, the communication path 304 comprises a combination of conductive traces, conductive wires, connectors, and buses that cooperate to permit the transmission of electrical data signals to components such as processors, memories, sensors, input devices, output devices, and communication devices. Accordingly, the communication path 304 may comprise a CAN bus, a VAN bus, and the like. Additionally, it is noted that the term “signal” means a waveform (e.g., electrical, optical, magnetic, mechanical or electromagnetic), such as DC, AC, sinusoidal-wave, triangular-wave, square-wave, vibration, and the like, capable of traveling through a medium.

The computing device 300 includes one or more memory modules 306 coupled to the communication path 304. The one or more memory modules 306 may comprise RAM, ROM, flash memories, hard drives, or any device capable of storing machine readable and executable instructions such that the machine readable and executable instructions can be accessed by the processor 302. The machine readable and executable instructions may comprise logic or algorithm(s) written in any programming language of any generation (e.g., 1GL, 2GL, 3GL, 4GL, or 5GL) such as, for example, machine language that may be directly executed by the processor, or assembly language, object-oriented programming (OOP), scripting languages, microcode, etc., that may be compiled or assembled into machine readable and executable instructions and stored on the one or more memory modules 306. Alternatively, the machine readable and executable instructions may be written in a hardware description language (HDL), such as logic implemented via either a field-programmable gate array (FPGA) configuration or an application-specific integrated circuit (ASIC), or their equivalents. Accordingly, the methods described herein may be implemented in any conventional computer programming language, as pre-programmed hardware elements, or as a combination of hardware and software components.

The computing device 300 comprises a data storage component 308. The data storage component 308 may store data used by various components of the computing device 300. In addition, the data storage component 308 may store FPGA firmware bit files to be analyzed by the computing device 300.

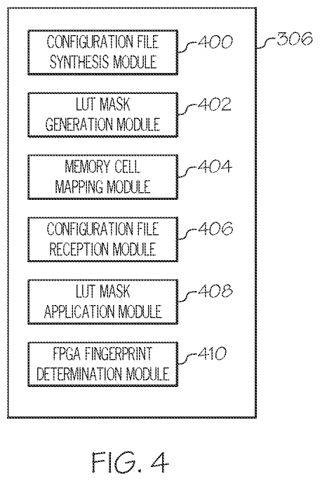

Now referring to FIG. 4, the memory modules 306 of the computing device 300 are schematically shown. The memory modules 306 include a configuration file synthesis module 400, a LUT mask generation module 402, a memory cell mapping module 404, a configuration file reception module 406, a LUT mask application module 408, and an FPGA fingerprint determination module 410. Each of the configuration file synthesis module 400, the LUT mask generation module 402, the memory cell mapping module 404, the configuration file reception module 406, the LUT mask application module 408, and the FPGA fingerprint determination module 410 may be a program module in the form of operating systems, application program modules, and other program modules stored in the one or more memory modules 306. Such a program module may include, but is not limited to, routines, subroutines, programs, objects, components, data structures and the like for performing specific tasks or executing specific data types as will be described below.

The configuration file synthesis module 400 may be used to synthesize two FPGA configuration files for an FPGA that may be used to generate a LUT mask for an FPGA, as disclosed herein. In particular, the configuration file synthesis module 400 may generate a first configuration file B, and a second configuration file BI, in which all of the LUT bits in B are the inverse of the LUT bits in BI. That is, every LUT bit that is a ‘1’ in configuration B will be a ‘0’ in configuration file BI, and every LUT bit that is a ‘0’ in configuration file B will be a ‘1’ in configuration file BI.

Furthermore, the configuration file synthesis module 400 may generate the two configuration files such that the non-LUT bits are the same in both B and BI. As such, the bits that are different between the two synthesized configuration files B and BI indicate positions of the LUT bits of a configuration file associated with the FPGA. Accordingly, a bit-wise exclusive or (XOR) function may be performed on the bits of the two configuration files B and BI to generate the LUT mask associated with the FPGA, as disclosed herein.

In embodiments, hardware description language (HDL) code is used to generate the two configuration files B and BI, as disclosed herein. A computer-aided design (CAD) program may utilize the HDL code to synthesize the configuration files. In order to generate the two configuration files B and BI without requiring any FPGA specific components or configuration files a set of connected HDL CASE statements are used, as disclosed herein. There is one CASE statement for each LUT in the target FPGA, and by connecting the CASE statements to each other using special patterns, it can be ensured with a high degree of probability that the desired function is mapped to the same LUT location for both B and BI.

In order to generate the two configuration files B and BI such that only the LUT bits are different between the two configuration files, an arbitrary function is consistently placed in a specific LUT location while the two configuration files are generated. By maintaining consistent placement, the same LUT memory cell functions are consistently mapped to the same bits in a configuration file. In particular, input bits to LUTs are mapped to output bits of other LUTs, as disclosed herein. It should be understood that explicit locations are not needed, rather relative locations can be used to build a sea of interconnected LUTs or functions to determine what is mapped onto the FPGA.

In a first example, a row/column approach is used. In this example, we assume that the target FPGA has a 2-dimensional array of LUTs. Most FPGA layouts can be broken into subsections having a consistent number of rows and columns. As such, this assumption holds for most FPGAs. In this example, it is assumed that a target FPGA has R rows and C columns of LUTs. In some examples, the number of rows and columns in the target FPGA may be determined from the data book associated with the target FPGA.

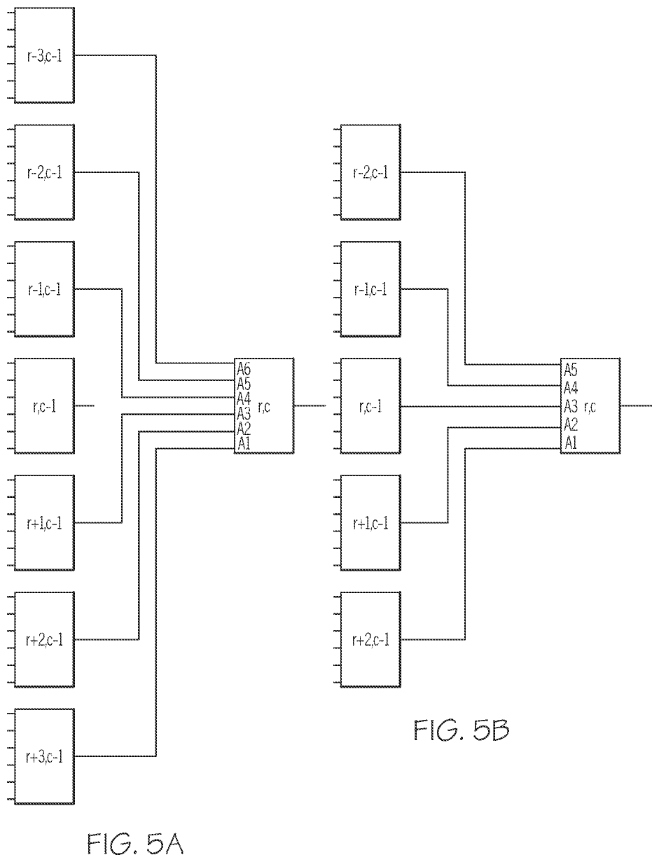

FIG. 5A shows an example input signal connection used for an FPGA that has LUTs with an even number of inputs (6 inputs in the example of FIG. 5A), and FIG. 5B shows an example input signal connection used for an FPGA that has LUTs with an odd number of inputs (5 inputs in the example of FIG. 5B).

In the example of FIG. 5A, a LUT at position (r,c), that is at row r and column c, has input bits routed to the output of other LUTs as shown. In particular, in the example of FIG. 5A, the target FPGA has LUTs with 6 inputs A1, A2, A3, A4, A5, A6. In the example of FIG. 5A, input A1 is routed to the output of the LUT at position (r+3,c−1), input A2 is routed to the output of the LUT at position (r+2,c−1), input A3 is routed to the output of the LUT at position (r+1,c−1), input A4 is routed to the output of the LUT at position (r−1,c−1), input A5 is routed to the output of the LUT at position (r−2,c−1), and input A6 is routed to the output of the LUT at position (r−3,c−1).

In the example of FIG. 5B, the target FPGA has LUTs with 5 inputs A1, A2, A3, A4, A5. In the example of FIG. 5B, input A1 is routed to the output of the LUT at position (r+2,c−1), input A2 is routed to the output of the LUT at position (r+1,c−1), input A3 is routed to the output of the LUT at position (r,c−1), input A4 is routed to the output of the LUT at position (r−1,c−1), and input 5 is routed to the output of the LUT at position (r−2,c−1).

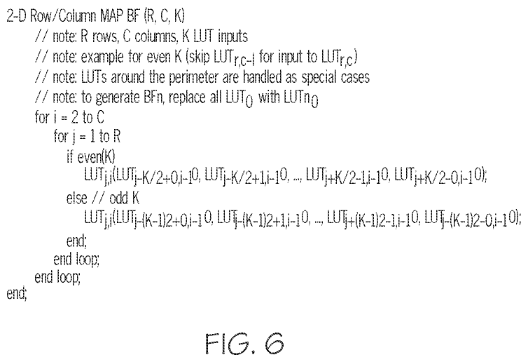

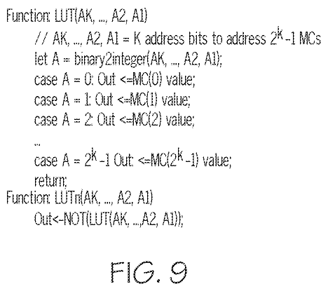

The input signal connections in FIGS. 5A and 5B may be reduced for FPGAs with LUTs having less than 5 inputs or extended for FPGAs with LUTs having more than 6 inputs, by following the same pattern. The connections for LUTs around the periphery may be modified to accommodate FPGA edge overflow. For example, the inputs to the LUTs in the first column of the FPGA may be driven by FPGA input pins, rather than other LUTs. FIG. 6 shows pseudocode for generating the input signal connections of FIGS. 5A and 5B. In the example of FIG. 6, the function LUT is called, which is discussed below with reference to FIG. 9.

The example input signal connections described above and shown in FIGS. 5A and 5B ensure consistent ordering of inputs to the LUTs such that when the two configuration files B and BI are synthesized by setting the LUT memory cells values as discussed below, the interconnect bits in both configuration files will be the same and only the LUT bits will be different. However, generating the input signal connections of FIGS. 5A and 5B requires knowledge of the number of rows and columns of the target FPGA, which may not be readily obtainable. As such, a second example of input signal connections is described below, which does not rely on this knowledge.

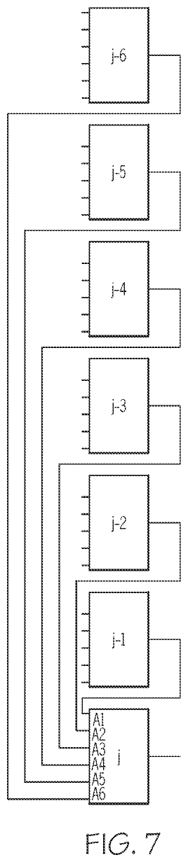

In the second example, only knowledge of the total number of LUTs in the target FPGA is required, which is readily obtainable (e.g., from the data book associated with the target FPGA). FIG. 7 shows an example input signal connection used for the target FPGA in the second example. In this example, a snake mapping approach is used. In the example of FIG. 7, it is assumed that each LUT of the target FPGA has 6 inputs, however the input signal connection may be easily modified for FPGAs having LUTs with more or less than 6 inputs.

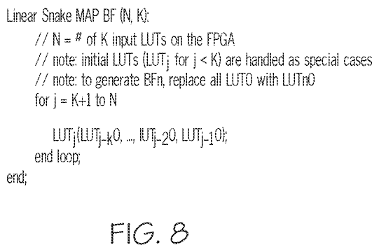

In the example of FIG. 7, for a LUT j in the target FPGA, input A1 is routed to the output of LUT j−1, input A2 is routed to the output of LUT j−2, input A3 is routed to the output of LUT j−3, input A4 is routed to the output of LUT j−4, input A5 is routed to the output of LUT j−5, and input A6 is routed to the output of LUT j−6. The inputs to the first 6 LUTs of the FPGA may be routed to FPGA input pins rather than other LUTs. Pseudocode for generating the input signal connection of FIG. 7 is shown in FIG. 8, where the function LUT is discussed below with reference to FIG. 9. Similar to the example of FIGS. 5A and 5B, the input signal connection of FIG. 7 ensures than when the two configuration files B and BI are synthesized by setting the LUT memory cells values as discussed below, the interconnect bits in both configuration files will be the same and only the LUT bits will be different.

Once the input connections to the LUTs of the target FPGA are mapped as discussed above as shown in either the example of FIGS. 5A and 5B or as shown in the example of FIG. 7, the memory cells of the LUTs may be set as shown herein. However, various considerations are taken into account when setting the values of the memory cells to be programmed by the synthesized configuration files. As discussed above, a CAD program may be used to synthesize configuration files based on programming instructions. However, even when the input signal connections are set as discussed above, there are certain situations where CAD programs modify the interconnect bits for certain LUT bit configurations, even with logic optimization turned off, as discussed in further detail below. As such, the LUT memory cells to be used to generate the configuration files must be carefully be chosen.

In embodiments, the computing device 300 may use a CAD program to compile HDL code to generate configuration files for a target FPGA, as disclosed herein. The HDL code may specify input signal connections, as discussed above. However, many compilers may reorder the LUT input pin assignments to improve or reduce timing delays, even with logic optimization turned off. Such input reordering changes the addresses of the bits used to program the LUTs. As such, if input pin reordering occurs, it may interfere with LUT mask generation. In particular, the LUT bits in the configuration files B and BI, discussed above, may not line up, and the LUT mask may not be able to be generated using these two configuration files. In embodiments, this problem, may be overcome by using Hamming functions of the LUT input address, as discussed in further detail below. This prevents input address bits from being transposed during generation of the configuration files B and BI.

Another potential issue is that some compilers perform logic reduction due to input pin elimination. In particular, even with logic optimization disabled, some compilers still perform optimizations on any LUT equations that can be reduced to few than K inputs. For example, the K=4 input LUT function “0 1 0 1 0 1 0 1 0 1 0 1 0 1 0 1” can be reduced to a function of just its least significant address bit. Similar to pin reordering discussed above, this may also disrupt mask creation since the LUT bits of B and BI may not line up. To overcome this issue, the only functions that are used are XOR, XNOR, and Hamming, which require all input address bits as discussed in further detail below.

Another potential issue associated with the row and column and snake patterns discussed above is that external inputs pints are needed to drive the LUT inputs at the start of the patterns. In the snake pattern, the initial LUTs next to each other in the chain share all but one of their inputs. In this instance, some compilers merge those LUTs into a single LUT by decomposing the shared inputs to drive several smaller LUTs whose outputs connected to multiplexers driven by the non-shared inputs to the two separate LUTs. Accordingly, in embodiments, the initial LUTs in the snake pattern are connected such that none of the initial LUTs share multiple inputs to avoid this merging.

Turning now to FIG. 9, pseudocode is shown for the function LUT is shown, which is called by the pseudocode of both FIG. 6 and FIG. 8. The example of FIG. 9 also defines the function LUTn, which generates LUT outputs that are the inverse of LUTs generated using the LUT function. Accordingly, the function LUT may be used to generate the configuration file B, and the function LUTn may be used to generate the configuration file BI.

The function LUT of FIG. 9 assigns output values for a LUT. As such, when used in conjunction with the pseudocode of FIG. 6 or FIG. 8, output values are specified for all LUTs in an FPGA. The example of FIG. 9 uses connected HDL case statements to define the LUT functions. In the example of FIG. 9, the LUTs of the target FPGA have K inputs, and as such, the memory cell addresses range from 0 to 2^{K}−1. The function LUT then defines the LUT output based on the address of the LUT. For the LUT with address 0, the LUT output is assigned the value of memory cell 0, for the LUT with address 1, the LUT output is assigned the value of memory cell 1, for the LUT with address 2, the LUT output is assigned the value of memory cell 2, and so on for each LUT up to the LUT with address 2^{K}−1.

In addition to the LUT function shown in FIG. 9, individual values of the LUT memory cells may also be defined, as disclosed herein. In particular, the memory cell values may be defined based on XOR, XNOR, or Hamming functions of the LUT input address bits. As discussed above, these functions require the use of all LUT inputs, and as such, none of them are optimized away, and the LUT inputs are not transposed during successive FPGA configuration file synthesis.

In embodiments, Hamming functions of an LUT's input address bits are functions that place logic ‘1’ only in LUT memory cells whose input address bits have the same Hamming weight. For example, a K=4 input LUT has address bits, A=0000, 0001, 0010, 0011, 0100, 0101, 0110, 0111, 1000, 1001, 1010, 1011, 1100, 1101, 1110 and 1111. The address with a Hamming weight of 0 is A=0000. The addresses with Hamming weight of 1 are 0001, 0010, 0100, and 1000. The addresses with Hamming weight of 2 are 1100, 0101, 0110, 1001, 1010, and 1100. The addresses with Hamming weight of 3 are 0111, 1011, 1101, and 1110. The only address with Hamming weight of 4 is 111. Given a K input LUT with even K, Hamming weight of K/2 works best.

Two functions that satisfy these hamming weight requirements are XOR and XNOR. Accordingly, in one example, the LUT memory cell values may be assigned by performing an XOR operation on the input address bits. In another example, the LUT memory cell values may be assigned by performing an XNOR operation on the input address bits.

In embodiments, the configuration file synthesis module 400 uses a CAD program to generate the configuration file B using the input signal connections of the row/column pattern shown in FIGS. 5A and 5B or the snake pattern shown in FIG. 7 along with the function LUT function shown in FIG. 9, and memory cell values defined as either an XOR operation or XNOR operation performed on the input address bits. In addition, the configuration file synthesis module 400 uses the CAD program to generate the configuration file BI using the same input signal connections, the function LUTn shown in FIG. 9, and memory cells values defined as the inverse values used for the configuration file B (e.g., if the memory cells of the configuration file B were defined using XOR, then the memory cells of the configuration file BI are defined using XNOR, and vice versa). As such, the configuration files B and BI will have the same values for non-LUT bits and inverse values for LUT bits.

Referring back to FIG. 3, the LUT mask generates the LUT mask for the target FPGA based on the configuration files B and BI, as disclosed herein. In particular, the LUT mask generation module 402 performs a bit-wise XOR operation between the configuration files B and BI to generate the LUT mask. Because the two configuration files have the same non-LUT bits, the bit-wise XOR operation will result in all non-LUT bits being ‘0’. However, because the two configuration files have inverse values for all the LUT memory cells bits, the bit-wise XOR operation will result in all LUT bits being ‘1’. Thus, the bit-wise XOR operation between the two configuration files will generate a LUT mask that can be applied to any configuration file to be used with the target FPGA to determine which bits of the configuration file correspond to LUT bits.

Referring still to FIG. 4, the memory cell mapping module 404 maps the memory cell LUT bits specified by the LUT mask to specific LUTs of the target FPGA. In particular, the memory cell mapping module 404 uses a combination of marching l's and 0's, random functions, and a log based binary search algorithm to narrow down and determine specific LUT bits, as disclosed herein.

While the LUT mask determined by the LUT mask generation module 402 identifies which configuration file bits are LUT bits, it does not determine which LUT bits correspond to specific LUTs in the target FPGA. Accordingly, this may be determined by the memory cell mapping module 404. In particular, the memory cell mapping module 404 may use a CAD program to generate a new configuration file in which the memory cells of one LUT are defined based on an XOR operation performed on the input address bits and the memory cells of every other LUT are defined based on an XNOR operation performed on the input address bits.

Using XOR and XNOR operations ensures that the CAD program will not perform pin reordering, logic reduction, or LUT merging, as discussed above. In addition, by only defining one LUT using XOR and the other LUTs using XNOR, the LUT mask generated by the LUT mask generation module 402 may be applied to the new configuration file generated by the memory cell mapping module 404 to identify the LUT bits. The identified LUT bits may then be analyzed to identify the bits defined by XOR rather than XNOR, and the location of the identified bits in the configuration file may be identified as the LUT bits associated with the particular LUT that was defined by the XOR operation. This procedure may be repeated for each LUT of the FPGA to identify the bit locations in the configuration file associated with each LUT. In some examples, the memory cell mapping module 404 may generate the new configuration file using XNOR to define the memory cell values of one LUT and using XOR to define the memory cell values of every other LUT.

The procedure above may be performed N times, where N is the number of LUTs in the FPGA, to identify the bit locations in the configuration file of each LUT in the FPGA. However, in another example, a log based binary search algorithm may be used to reduce the number of iterations needed to be performed. In particular, on the first iteration, a single LUT may be identified. Then on the next iteration, two LUTs may be identified. On subsequent iterations, four LUTs, then eight LUTs, and so on may be identified. As such, the number of iterations may be reduced from N to O(log N) to identify the locations of the bit values of every LUT of the FPGA in the configuration file.

Referring back to FIG. 4, the configuration file reception module 406 receives a FPGA configuration bit file to be analyzed using the techniques described above. In some examples, the configuration file may be obtained from a third party vendor. In other examples, the configuration file may be read out from an already programmed FPGA. After the configuration file reception module 406 receives a configuration file, it may be analyzed as disclosed in further detail below.

Referring still to FIG. 4, the LUT mask application module 408 may apply a LUT mask generated by the LUT mask generation module 402 to a configuration file received by the configuration file reception module 406. As discussed above, the LUT mask file may contain values of ‘ 1’ for LUT bits and values of ‘0’ for other bits. As such, the LUT mask application module 408 may extract the bits from the configuration file received by the configuration file reception module 406 at positions of the LUT mask having a value of ‘1’ in order to extract only the LUT bits from the configuration file. This may identify the values to be loaded into the LUT memory cells of the target FPGA when programmed with the received configuration file. The memory cells bits may then be further analyzed to determine the functionality of the programmed target FPGA, and to determine whether the received configuration file will implement any malicious or unexpected functionality.

Referring still to FIG. 4, the FPGA fingerprint determination module 410 may determine a memory-based physical unclonable function (PUF) fingerprint for the target FPGA, as disclosed herein. In some examples for hardware watermarking or metering, it may be desirable to determine a memory PUF fingerprint for the target FPGA. That is, it may be desirable to determine a uniquely identifiable signature associated with a specific FPGA. As such, after initially determining a signature or fingerprint associated with an FPGA, the fingerprint may be read out from the FPGA in the future in the event that there is any question about the authenticity of the FPGA (e.g., if there is concern that a counterfeit FPGA is being passed off as the authentic FPGA).

One such fingerprint may comprise the initial LUT memory cell values of an FPGA before the FPGA is programmed. And because the LUT mask disclosed herein can identify the locations of a LUT bits, the LUT mask may be used to determine a fingerprint for the FPGA. In embodiments, to determine a fingerprint for an FPGA, the FPGA can be powered on before it is programmed and the programming file can be read out. Because the FPGA has not been programmed, the values of the memory cells can be used as a unique memory PUF fingerprint for the FPGA. Accordingly, the FPGA fingerprint determination module 410 may apply the LUT mask associated with the FPGA to the read out programming file to identify the values of the uncommitted FPGA LUT memory cells at power up. The values of these uncommitted FPGA LUT memory cells may be used as a fingerprint for the FPGA.

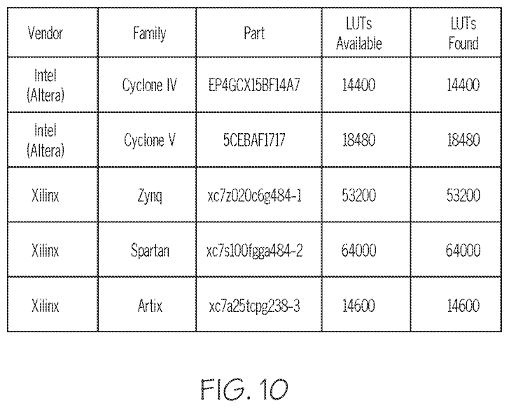

The techniques disclosed herein were tested on a variety of Xilinx and Intel/Altera FPGAs. The disclosed techniques were used to generate LUT mask files to identify LUT programming bits in each of the FPGAs that were tested. Once the LUT mask was found for each device, it took O(log N) additional configurations to determine the location of each specific programming bit in the FPGA configuration file. The testing results are summarized in the table shown in FIG. 10. As shown in FIG. 10, the LUT memory cells were successfully identified for each of the FPGAs tested.

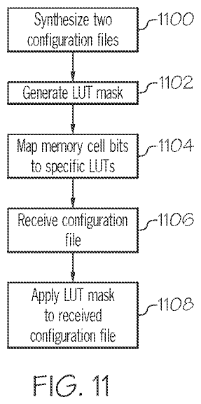

FIG. 11 depicts a flowchart of an example method that may be performed by the computing device 300 to identify LUT bits for a configuration file associated with a target FPGA. At step 1100, the configuration file synthesis module 400 synthesizes two configuration files for the target FPGA, as discussed above. In particular, the configuration file synthesis module 400 uses a CAD tool to synthesize two configuration files for the target FPGA based on a defined input signal connection for the target FPGA and defined values of the memory cells of the LUTs of the FPGA. In one example, the input signal connection may be based on the row/column pattern described above. In another example, the input signal connection may be based on the snake pattern described above. The memory cell values may be defined as LUT functions based on XOR, XNOR, or Hamming functions of the LUT's input address bits, as described above. As such, the two synthesized configuration files will have the same bit values for interconnect bits and inverse bit values for LUT bits.

At step 1102, the LUT mask generation module 402 generates a LUT mask for the target FPGA as described above. In particular, the LUT mask generation module 402 performs a bit-wise XOR operation between the two configuration files generated by the configuration file synthesis module 400 to generate the LUT mask. At step 1104, the memory cell mapping module 404 maps the LUT bits identified by the LUT mask to specific LUTs of the target FPGA, as described above.

At step 1106, the configuration file reception module 406 receives a configuration file to be used to program the target FPGA. At step 1108, the LUT mask application module 408 applies the LUT mask to the received configuration file to identify the bits of the configuration file to be loaded onto the memory cells of the LUT of the target FPGA.

It should now be understood that embodiments described herein are directed to fast FPGA reverse engineering for hardware metering and fingerprinting. The techniques disclosed herein allow for the identification of the LUT bits of a configuration file associated with a target FPGA without the need for any special knowledge about the FPGA. As such, the bits to be loaded onto LUTs of an FPGA can be quickly and easily determined. The techniques disclosed herein can also be used to easily identify a fingerprint associated with an FPGA.

What is claimed is:

1. An apparatus comprising a processor configured to:
synthesize a first configuration file associated with a target field-programmable gate array (FPGA), and a second configuration file associated with the target FPGA, wherein first look-up-table (LUT) bits of the first configuration file are the logical inverse of second LUT bits of the second configuration file, and first non-LUT bits of the first configuration file are the same as second non-LUT bits of the second configuration file; and
generate a LUT mask indicating which bits of the first configuration file and the second configuration file correspond to the first LUT bits and the second LUT bits by performing a bit-wise exclusive OR operation between the first configuration file and the second configuration file.

2. The apparatus of claim 1, wherein the processor is further configured to:
synthesize the first configuration file and the second configuration file such that first input signal connections of first LUTs in the first configuration file are the same as second input signal connections of second LUTs in the second configuration file.

3. The apparatus of claim 2, wherein the first input signal connections and the second input signal connections cause each LUT in the target FPGA to receive, as inputs, outputs from a plurality of LUTs in a previous column of look-up-tables.

4. The apparatus of claim 2, wherein the first input signal connections and the second input signal connections cause each LUT in the target FPGA to receive, as inputs, outputs from a plurality of previous, adjacent LUTs.

5. The apparatus of claim 1, wherein the first configuration file is synthesized such that the values of memory cells in the LUTs are defined based on an exclusive OR operation between input address bits of the LUTs.

6. The apparatus of claim 1, wherein the first configuration file is synthesized such that the values of memory cells in the LUTs are defined based on an exclusive NOR operation between input address bits of the LUTs.

7. The apparatus of claim 1, wherein the processor is further configured to:
synthesize a third configuration file associated with the target FPGA, wherein memory cells for a first LUT of the third configuration file are defined based on an exclusive OR operation between input address bits of the first LUT, and memory cells for the other LUTs of the third configuration file are defined based on an exclusive NOR operation between input address bits of the other LUTs;
apply the LUT mask to the third configuration file to identify LUT bits of the third configuration file; and
determine which bits of the third configuration file are associated with the first LUT based on the identified LUT bits of the third configuration file.

8. The apparatus of claim 7, wherein the processor is further configured to:
generate additional configuration files using a log based binary search algorithm;
apply the LUT mask to the additional configuration files to identify LUT bits of the additional configuration files; and
determine which bits of the third configuration file are associated with each LUT of the target FPGA based on the identified LUT bits of the additional configuration files.

9. The apparatus of claim 1, wherein the processor is further configured to:
receive a fourth configuration file associated with the target FPGA; and
apply the LUT mask to the fourth configuration file to determine which bits of the fourth configuration file correspond to memory cell bits of the target FPGA.

10. The apparatus of claim 1, wherein the processor is further configured to:
receive a read out of the programming file of the target FPGA before the target FPGA is programmed;
apply the LUT mask to the read out of the programming file of the target FPGA before the target FPGA is programmed to identify uncommitted memory cell values of the target FPGA; and
determine a fingerprint associated with the target FPGA based on the uncommitted memory cell values of the target FPGA.

11. A method comprising:
synthesizing a first configuration file associated with a target field-programmable gate array (FPGA), and a second configuration file associated with the target FPGA, wherein first look-up-table (LUT) bits of the first configuration file are the logical inverse of second LUT bits of the second configuration file, and first non-LUT bits of the first configuration file are the same as second non-LUT bits of the second configuration file; and
generating a LUT mask indicating which bits of the first configuration file and the second configuration file correspond to the first LUT bits and the second LUT bits by performing a bit-wise exclusive OR operation between the first configuration file and the second configuration file.

12. The method of claim 11, further comprising:
synthesizing the first configuration file and the second configuration file such that first input signal connections of first LUTs in the first configuration file are the same as second input signal connections of second LUTs in the second configuration file.

13. The method of claim 12, wherein the first input signal connections and the second input signal connections cause each LUT in the target FPGA to receive, as inputs, outputs from a plurality of LUTs in a previous column of look-up-tables.

14. The method of claim 12, wherein the first input signal connections and the second input signal connections cause each LUT in the target FPGA to receive, as inputs, outputs from a plurality of previous, adjacent LUTs.

15. The method of claim 11, wherein the first configuration file is synthesized such that the values of memory cells in the LUTs are defined based on an exclusive OR operation between input address bits of the LUTs.

16. The method of claim 11, wherein the first configuration file is synthesized such that the values of memory cells in the LUTs are defined based on an exclusive NOR operation between input address bits of the LUTs.

17. The method of claim 11, further comprising:
synthesizing a third configuration file associated with the target FPGA, wherein memory cells for a first LUT of the third configuration file are defined based on an exclusive OR operation between input address bits of the first LUT, and memory cells for the other LUTs of the third configuration file are defined based on an exclusive NOR operation between input address bits of the other LUTs;
applying the LUT mask to the third configuration file to identify LUT bits of the third configuration file; and
determining which bits of the third configuration file are associated with the first LUT based on the identified LUT bits of the third configuration file.

18. The method of claim 17, further comprising:
generating additional configuration files using a log based binary search algorithm;
applying the LUT mask to the additional configuration files to identify LUT bits of the additional configuration files; and
determining which bits of the third configuration file are associated with each LUT of the target FPGA based on the identified LUT bits of the additional configuration files.

19. The method of claim 11, further comprising:
receiving a fourth configuration file associated with the target FPGA; and
applying the LUT mask to the fourth configuration file to determine which bits of the fourth configuration file correspond to memory cell bits of the target FPGA.

20. The method of claim 11, further comprising:
receiving a read out of the programming file of the target FPGA before the target FPGA is programmed;
applying the LUT mask to the read out of the programming file of the target FPGA before the target FPGA is programmed to identify uncommitted memory cell values of the target FPGA; and
determining a fingerprint associated with the target FPGA based on the uncommitted memory cell values of the target FPGA.
